(19) United States
(12) Patent Application Publication
(10) Pub. No.: US 2006/0078021 A1
(43) Pub. Date: Apr. 13, 2006

(54) Semiconductor laser unit and optical pickup device including the semiconductor laser unit

(75) Inventors: Kiyoshi Fujihara, Ootsu-shi (JP); Masanori Minamio, Osaka (JP); Masaya Tateyanagi, Moriyama-shi (JP); Shigeki Okamoto, Ukyou-ku (JP)

Correspondence Address: GREENBLUM & BERNSTEIN, P.L.C., 1950 ROLAND CLARKE PLACE, RESTON, VA, 20191, US

(73) Assignee: Matsushita Electric Industrial Co., Ltd., Osaka (JP)

(21) Appl. No.: 11/247,283

(22) Filed: Oct. 12, 2005

(30) Foreign Application Priority Data
Oct. 13, 2004 (JP) 2004-298498

(51) Int. Cl. H01S 5/00

(52) U.S. Cl. 372/43.01

(57) ABSTRACT

The present invention provides a semiconductor laser unit which realizes efficient heat dissipation, reduction in size, high-density integration of optical elements, prevention of a light-receiving element from being polluted with dust, and simple structure for easy assembly. The semiconductor laser unit includes: (a) a metal plate having a first recessed portion in a central part of an upper surface of the metal plate; (b) a flexible printed circuit which has wiring patterns, and a first aperture positioned on the first recessed portion, and is bent at both ends and in contact with the first recessed portion and a pair of side surfaces of the metal plate; (c) a light-emitting/receiving unit which includes a light-emitting element and a light-receiving element, and is placed on the first recessed portion through the first aperture; (d) a frame having: side portions for fixing firmly, on the side surfaces of the metal plate, the flexible printed circuit which is in contact with the side surfaces; and a top portion which has a second aperture and is placed on a protruding portion of the metal plate so that the first recessed portion is covered with the top portion and the second aperture faces toward the first recessed portion; and (e) an optical element which covers the second aperture.

### BACKGROUND OF THE INVENTION

(1) Field of the Invention

The present invention relates to a semiconductor laser unit, and particularly to a semiconductor laser unit used for an optical pickup for writing information to and reading the written information from a recording medium, for example, an optical disc such as a digital versatile disc (DVD) and a compact disc (CD), and to an optical pickup device including such semiconductor laser unit.

(2) Description of the Related Art

In recent years, recording media of CD type (such as CD-ROM, CD-R and CD-RW) and DVD type (such as DVD-ROM, DVD-RW and DVD-RAM) have spread rapidly, as recording media not only for music information but also for video information. With the increasing use of such recording media, optical disk drives for writing information to and reading the written information from the recording media have also spread rapidly. An optical pickup device that is the main part of such an optical disk drive is strongly required to have higher power for faster recording, higher performance satisfying both CD and DVD standards, and reduction in size for a slimmer optical disk drive. Therefore, a semiconductor laser unit used for such optical pickup device is required to improve the heat dissipation efficiency of the package for achieving higher optical power, to increase the integration density of an increased number of pins for achieving higher performance, and to reduce the package width for achieving reduction in size.

A description of a conventional semiconductor laser unit in an optical pickup device is as follows, with reference to FIGS. 1A and 1B, taking a semiconductor laser unit described in Japanese Patent No. 3412609 Publication (Reference 1) as an example.

FIG. 1A is a top view of a conventional semiconductor laser unit, and FIG. 1B is a section view (section X-X′ in FIG. 1A) of the semiconductor laser unit.

The semiconductor laser unit shown in FIGS. 1A and 1B includes: a lead frame 700; a molded-resin package 710; a silicon substrate 730 having a light-receiving element 720, a 45-degree angle reflecting mirror for reflecting laser light upward of the package 710, and a circuit for receiving and processing the light reflected from an optical disk; a semiconductor laser 740 mounted onto the silicon substrate and disposed on the center of the package 710 through the silicon substrate 730; and a hologram element 750 having a grating pattern 750b on its bottom and a hologram pattern 750a on the underside of its top.

As shown in FIG. 1B, in the above semiconductor laser unit, after the light 760 emitted from the semiconductor laser 740 is reflected upward of the package 710 by the reflecting mirror and diffracted by the grating pattern 750b, it passes through optical components (not shown in the diagrams) such as a collimator and an objective lens and arrives at the optical disk (not shown in the diagrams). The light 770 reflected from the optical disk returns the same path, and then after being diffracted by the hologram pattern 750a, it enters the light-receiving element 720 integrated in the signal processing circuit.

Two major problems to be solved occur when trying to achieve the higher optical power, higher performance and reduction in size of the optical pickup device including the semiconductor laser unit structured as mentioned above. One problem is to improve the heat dissipation efficiency for higher optical power, and another is to reduce the pin pitch for higher performance and reduction in size.

Generally speaking, an optical disk drive for high-speed recording requires high power light of 200 mW or more emitted from a semiconductor laser unit. In order to achieve such high power light, the driving current of the laser 740 increases, the temperature thereof rises, and thus the reliability thereof decreases. In order to stabilize the driving of the laser 740, the heat generated in the laser 740 has to be dissipated efficiently. However, since the above-mentioned conventional semiconductor laser unit includes the package 710 made of resin of low thermal conductivity (about 0.5 W/m/deg), its structure has high thermal resistance, which hinders the efficient heat dissipation.

In addition, when trying to miniaturize the package 710 having the structure of the above-mentioned conventional semiconductor laser unit, that is, when trying to reduce the width of the package 710, the increase in number of pins for higher performance is limited. That is because although there is a need to reduce the pin pitch in order to reduce the width of the package 710 and increase the number of pins, this is limited to about 0.4 mm in the current processing technology, and reduction beyond 0.4 mm is very difficult.

Next, a description of a semiconductor laser unit which solves the problem of improving heat dissipation efficiency follows, with reference to FIGS. 2A to 2C, taking a semiconductor laser unit described in Japanese Laid-Open Patent Application Publication No. 2003-67959 (Reference 2) as an example.

FIG. 2A is a top view of a semiconductor laser unit described in Reference 2, FIG. 2B is a section view (section Y-Y′ in FIG. 2A) of the semiconductor laser unit, and FIG. 2C is another section view (section Z-Z′ in FIG. 2A) of the semiconductor laser unit.

The semiconductor laser unit shown in FIGS. 2A to 2C includes: a semiconductor laser unit 800 including a semiconductor laser; a photodetector 810 including a light-receiving element; a metal substrate 820 on which the semiconductor laser unit 800 and the photodetector 810 are mounted; and a resin substrate 830 which has an aperture formed in the area where the semiconductor laser unit 800 and the photodetector 810 are mounted, on which a printed wiring pattern is formed, and which is mounted on the metal substrate 820.

The above-mentioned semiconductor laser unit is capable of dissipating the heat generated in the semiconductor laser efficiently from the underside of the metal substrate 820, and therefore solving the problem of improving heat dissipation efficiency.

Japanese Laid-Open Patent Application Publication No. 08-227532 (Reference 3) discloses an optical head device in which a flexible printed circuit having a notched part is attached on a plate, optical elements are mounted on the plate through the notched part, and the optical elements and the flexible printed circuit are connected by bonding wires.

FIG. 3 is an external view of an optical head device described in Reference 3. The optical head device shown in FIG. 3 includes: a plate 900 made of metal; a flexible printed circuit 920 which is attached on one side of the plate 900, and on a part of which a notched part 910 is formed for exposing the surface of the plate 900; optical elements 930, 940 and 950 mounted on the plate 900 through the notched part 910; and bonding wires used to connect the electrical connection parts of these optical elements 930, 940 and 950 and the wiring of the flexible printed circuit 920. Since the optical elements 930, 940 and 950 are mounted on the metal plate 900, the optical head device described in Reference 3 has the high heat dissipation efficiency.

Furthermore, Japanese Laid-Open Patent Application Publication No. 2002-198605 (Reference 4) discloses, for example, a semiconductor laser unit which solves the problem of reducing the pin pitch.

FIG. 4 is an external view of a semiconductor laser unit described in Reference 4. The semiconductor laser unit shown in FIG. 4 includes: a metal island 1000; a flexible printed circuit 1040 including outer sections 1010 and bending sections 1020 having top end portions 1030 bonded with the wires; a semiconductor laser 1050; and a light-receiving element 1060. Here, the wire pitch of the outer sections 1010 is set large in consideration that the semiconductor laser unit is implemented in an optical disk drive.

The above-mentioned semiconductor laser unit including the flexible printed circuit 1040 as a wiring substrate is capable of reducing the wire pitch, and therefore capable of solving the problem of reducing the pin pitch. In addition, since this semiconductor laser unit is capable of dissipating the heat generated in the semiconductor laser 1050 efficiently from the underside of the metal island 1000, another problem of improving the heat dissipation efficiency is also solved.

### SUMMARY OF THE INVENTION

However, there are the following drawbacks in the above-described conventional semiconductor laser units.

In the structure of the semiconductor laser unit described in Reference 2, when trying to reduce the width of the whole unit for miniaturization of the unit, only the width of the aperture of the resin substrate 830 needs to be reduced. In other words, only the area where the laser unit 800 and the photodetector 810 are mounted has to be reduced. However, as far as enhancement of performance concerned, the area where the laser unit 800 and the photodetector 810 are mounted can not be reduced. Therefore, the semiconductor laser unit of the above structure described in Reference 2 is not capable of balancing both reduction in size and enhancement of performance. In addition, there is no description in Reference 2 about a semiconductor laser unit including an optical element such as a diffraction grating. Therefore, the semiconductor laser unit described in Reference 2 has another problem that a lot of optical elements to be mounted in the optical disk drive cannot be firmly fixed in the package when considering higher-density integration of such optical elements.

In the structure of the optical head device described in Reference 3, it is difficult to slim the optical head because the flexible printed circuit 920 extends off the plate 900, although the heat dissipation efficiency is enhanced because the optical elements are mounted on the plate 900. In addition, the optical head device is manufactured by joining a plurality of housings (not shown in the diagrams) containing the optical elements. Therefore, it is highly possible that the optical elements mounted on the plate 900 are polluted with dust when the housings are joined, which makes it difficult to ensure the desired properties stably.

Furthermore, in the semiconductor laser unit described in Reference 4, the semiconductor laser 1050 (light-emitting element) and the light-receiving element 1060 are mounted on different portions, and the flexible printed circuit 1040 is attached to still another portion. Therefore, the process for manufacturing the semiconductor laser unit is complicated, which makes it difficult not only to reduce working hours but also to ensure the positional accuracy. There is another problem that the working processes become complicated and thus the adhesion strength can hardly be maintained because the top end portions 1030 of the flexible printed circuit 1040, which are electrically connected to the semiconductor laser 1050 and the light-receiving element 1060 by wire bonding, are bent as shown in FIG. 4 and attached to the metal island 1000.

In view of the above problems, an object of the present invention is to provide a semiconductor laser unit which achieves better heat dissipation efficiency, reduction in size, higher-density integration of optical elements, a dust-resistant light-emitting/receiving element, and a simple structure for easy assembly.

In order to achieve the above object, the semiconductor laser unit according to the present invention includes: a metal plate having a first recessed portion in a central part of an upper surface of the metal plate; a flexible printed circuit which has wiring patterns, and a first aperture positioned on the first recessed portion, and is bent at both ends and in contact with the first recessed portion and a pair of side surfaces of the metal plate; a light-emitting/receiving unit which includes a light-emitting element and a light-receiving element, and is placed on the first recessed portion through the first aperture; a frame having side portions and a top portion, the side portions fixing firmly, on the side surfaces of the metal plate, the flexible printed circuit which is in contact with the side surfaces, the top portion having a second aperture and being placed on a protruding portion of the metal plate so that the first recessed portion is covered with the top portion and the second aperture faces toward the first recessed portion; and an optical element which covers the second aperture.

The semiconductor laser unit according to the present invention having the above structure achieves better heat dissipation efficiency, reduction in size, higher-density integration of optical elements, a light-emitting/receiving element which prevents to attach dust, gas of an adhesive and the like, and easy assembly.

The protruding portion of the metal plate, surrounding the first recessed portion, may have a second recessed portion having a depth greater than the thickness of the top portion of the frame, so that the top portion of the frame is placed on the second recessed portion.

The optical element may have a pattern for diffracting incident light.

The metal plate may be made of metal including copper.

In the semiconductor laser unit according to the present invention, the light-emitting/receiving unit that is a heat generating source is placed in the first recessed portion of the metal plate. Therefore, the present invention produces an effect of realizing a semiconductor laser unit capable of achieving better heat dissipation efficiency. In other words, the present invention realizes an optical disk drive which can be used at a higher temperature than ever before.

In the semiconductor laser unit according to the present invention, both ends of the flexible printed circuit are bent and the frame fixes both ends so that they are in contact along a pair of side surfaces of the metal plate. Therefore, the flexible printed circuit does not extend off the optical pickup device in its thickness direction, and thus it becomes possible to achieve a slim optical pickup device.

Since the frame covers the light-emitting/receiving unit, it becomes possible to suppress entry of dust into the light-emitting/receiving unit when mounting the semiconductor laser unit in the optical pickup device. Therefore, it becomes possible to realize an optical pickup device with stable properties.

Furthermore, since the semiconductor laser unit according to the present invention has a fine-pitch wiring flexible printed circuit, it produces an effect of realizing a semiconductor laser unit which allows integration of an increased number of pins for higher performance. In other words, it becomes possible to realize a slim and multifunctional optical disk drive.

In addition, since the semiconductor laser unit according to the present invention includes optical elements for diffracting the light emitted from a light-emitting element and the light incident to a light-receiving element, it is capable of integrating a diffraction grating and a hologram element into itself, although they have been mounted outside a semiconductor laser unit conventionally. As a result, the present invention produces an effect of realizing a semiconductor laser unit which reduces the number of components of an optical disk drive. In other words, it becomes possible to realize a semiconductor laser unit which reduces the number of components of an optical pickup device, and therefore reduces costs.

As described above, the present invention not only meets the needs for higher performance and reduction in size of a semiconductor laser unit, but also provides an easy-to-assemble semiconductor laser unit with high heat dissipation efficiency, and its practical value is very high.

As further information about technical background to this application, the disclosure of Japanese Patent Application No. 2004-298498 filed on Oct. 13, 2004 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1A is a top view of a conventional semiconductor laser unit described in Reference 1;

FIG. 1B is a section view (section X-X′ in FIG. 1A) of the conventional semiconductor laser unit described in Reference 1;

FIG. 2A is a top view of a conventional semiconductor laser unit described in Reference 2;

FIG. 2B is a section view (section Y-Y′ in FIG. 2A) of the conventional semiconductor laser unit described in Reference 2;

FIG. 2C is another section view (section Z-Z′ in FIG. 2A) of the semiconductor laser unit described in Reference 2;

FIG. 3 is an external view of a conventional optical head device described in Reference 3;

FIG. 4 is an external view of a conventional semiconductor laser unit described in Reference 4;

FIG. 5A is a first exploded perspective view of a semiconductor laser unit of a first embodiment;

FIG. 5B is a second exploded perspective view of the semiconductor laser unit of the first embodiment;

FIG. 5C is a third exploded perspective view of the semiconductor laser unit of the first embodiment;

FIG. 6A is a top view of the semiconductor laser unit of the first embodiment;

FIG. 6B is a side view of the semiconductor laser unit of the first embodiment;

FIG. 7 is a diagram showing another placement of an optical element in a semiconductor laser unit which has the same effect as that of the first embodiment;

FIG. 8A is a first exploded perspective view of a semiconductor laser unit of a second embodiment;

FIG. 8B is a second exploded perspective view of the semiconductor laser unit of the second embodiment;

FIG. 8C is a third exploded perspective view of the semiconductor laser unit of the second embodiment;

FIG. 9A is a top view of the semiconductor laser unit of the second embodiment;

FIG. 9B is a side view of the semiconductor laser unit of the second embodiment;

FIG. 10A is a top view of an optical pickup device of a third embodiment; and

FIG. 10B is a section view of the optical pickup device of the third embodiment.

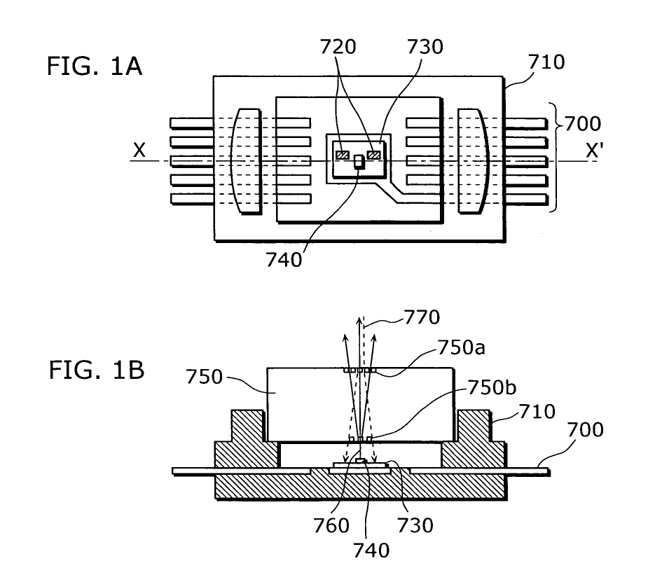

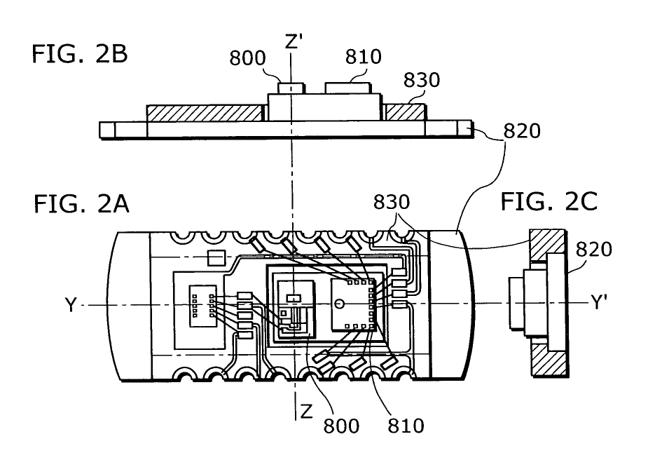

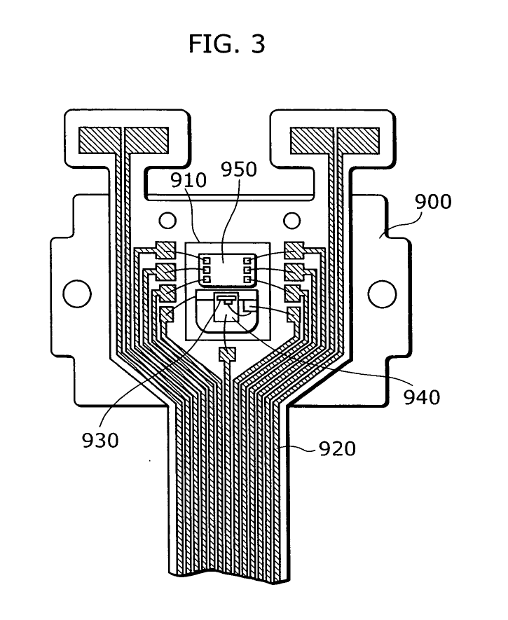

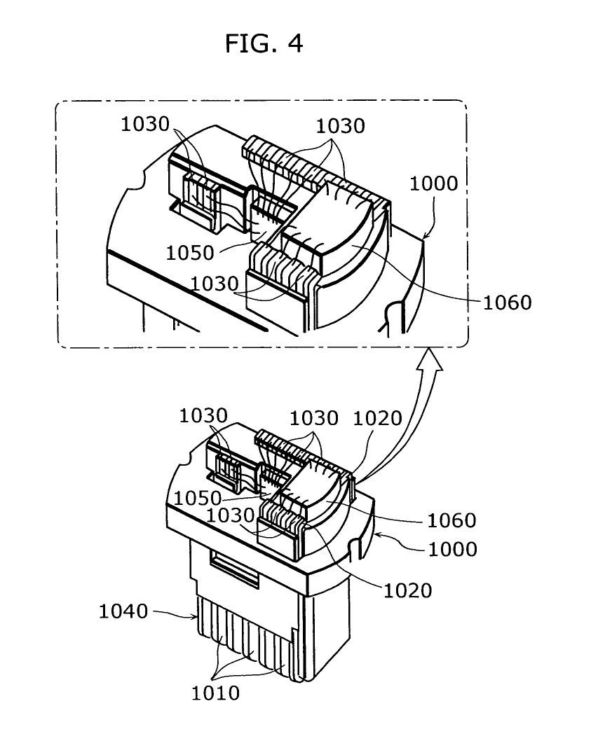

### DESCRIPTION OF THE PREFERRED EMBODIMENT(S)

The best mode for carrying out the present invention is described below with reference to the drawings.

### First Embodiment

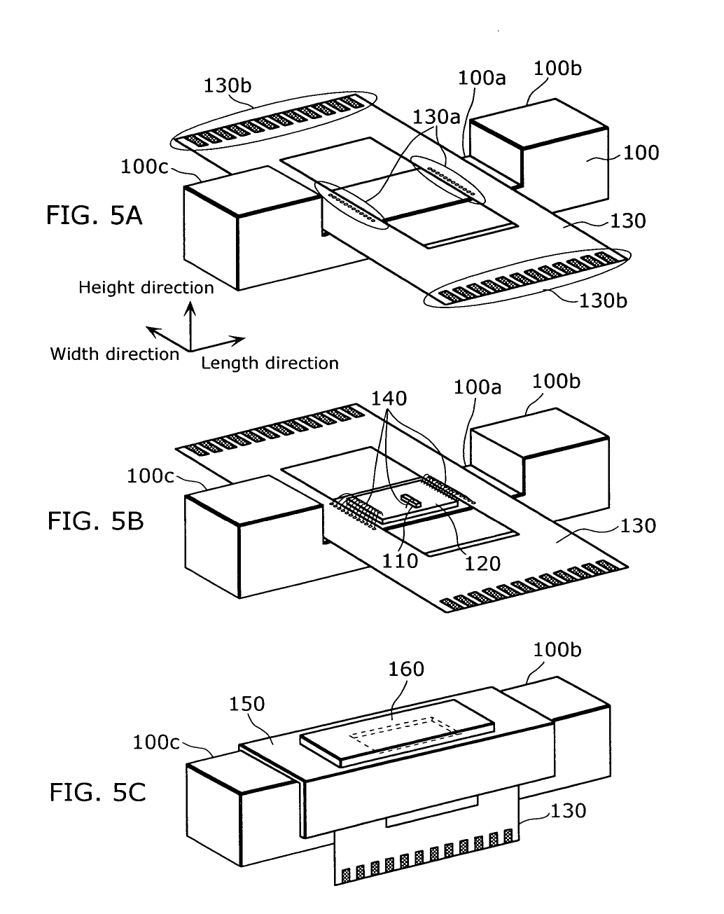

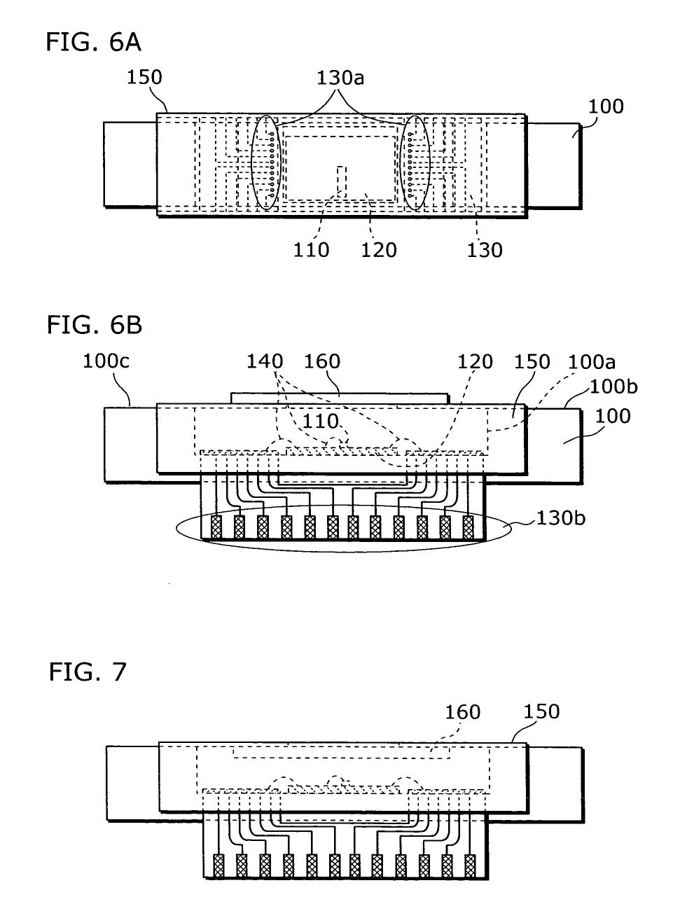

First, the semiconductor laser unit of the first embodiment is described with reference to FIGS. 5A to 5C and FIGS. 6A and 6B.

FIGS. 5A to 5C are exploded perspective views of the semiconductor laser unit of the first embodiment. FIG. 6A is a top view of the semiconductor laser unit of the first embodiment, and FIG. 6B is a side view of the semiconductor laser unit of the first embodiment.

The semiconductor laser unit of the first embodiment has an easy-to-assemble simple structure, and achieves easy heat dissipation, high performance and reduction in size thereof.

The structure of the semiconductor laser unit of the first embodiment is described below with reference to the exploded perspective views of FIGS. 5A to 5C.

First, as shown in FIG. 5A, the thickness of the central portion (hereinafter also referred to as “a recessed portion”) 100a in the length direction of a metal plate 100 is thinner than that of both end portions of the metal plate 100. A flexible printed circuit 130 with an aperture in the center and the greater width than that of the metal plate 100 is attached on the central portion 100a so that the aperture of the flexible printed circuit 130 is positioned on the recessed portion 100a of the metal plate 100. Note that both end portions of the metal plate 100 are also referred to as a protruding portion 100b and a protruding portion 100c hereinafter.

Next, as shown in FIG. 5B, a silicon substrate 120 on which a semiconductor laser is mounted is firmly fixed on the recessed portion 100a of the metal plate 100 through the aperture of the flexible printed circuit 130. Then, the terminals on the two portions (See the inner portions 130a of the flexible printed circuit 130 in FIG. 5A) located outside of the aperture of the flexible printed circuit 130 in the length direction are connected to the terminals on the silicon substrate 120 by wires 140.

Next, as shown in FIG. 5C, the parts of the flexible printed circuit 130 which extend off the metal plate 100 are bent along the sides of the metal plate 100. In order to fix the bent parts of the flexible printed circuit 130 on the sides of the metal place 100, the recessed portion 100a of the metal plate 100 is covered with a metal frame 150 having a top portion and side portions. More specifically, the recessed portion 100a of the metal plate 100 is covered with the frame 150 which is longer than the recessed portion 100a in the length direction and has a “U”-shaped cross section orthogonal to the length direction, so that the side portions of the frame 150 are fixed on the sides of the metal plate 100, and thus the bent parts of the flexible printed circuit 130 are firmly fixed on the sides of the metal plate 100.

It should be noted that the inside width of the frame 150 has the value obtained by adding twice the thickness of the flexible printed circuit 130 to the width of the metal plate 100. The height of the frame 150 is greater than the difference between the height of the end portions (protruding portions 100b and 100c) of the metal plate 100 and the height of the recessed portion 100a. The frame 150 covers the metal plate 100 so that the top portion of the frame 150 is positioned on the protruding portions 100b and 100c of the metal plate 100. Therefore, the frame 150 covers the recessed portion 100a so as to keep the space above the recessed portion 100a of the metal place 100. In addition, the frame 150 has an aperture in the area of its top portion which faces the recessed portion 100a. A glass plate optical element 160 which is larger than the aperture of the frame 150 is firmly fixed on the upper surface of the frame 150 so that the aperture is covered with the optical element 160.

Next, the structure of the semiconductor laser unit of the first embodiment is described in more detail with reference to FIGS. 6A and 6B.

As described with reference to FIGS. 5A to 5C, the semiconductor laser unit of the first embodiment includes the metal plate 100 which is made of nickel- and gold-plated copper and has the recessed portion 100a formed in its central part. The semiconductor laser unit of the first embodiment also includes the silicon substrate 120, on which the semiconductor laser 110, a 45-degree angle micromirror which is formed using the silicon (111) surface, a light-receiving element that is a photodetecting circuit and a signal processing circuit are integrated.

The semiconductor laser unit of the first embodiment also includes the flexible printed circuit 130 in which the wiring made of metal such as copper is sandwiched between resin such as polyimide, and the wires 140 which are made of gold and electrically connect the semiconductor laser 110, the silicon substrate 120 and the flexible printed circuit 130 to each other. The semiconductor laser unit of the first embodiment further includes the frame 150 which is made of metal and used for fixing the flexible printed circuit 130, with its end portions being bent, on the sides of the metal plate 100, and the optical element 160 of a glass plate which is placed on the upper surface of the frame 150 so as to cover the aperture thereof and allows the light emitted from the semiconductor laser 110 and the light incident on the light-receiving element to pass through.

As shown in FIG. 5B and FIG. 6B, the metal plate 100 is formed so that the thickness of the area of the metal plate 100 where the flexible printed circuit 130 and the silicon substrate 120 are mounted (the recessed portion 100a of the metal plate 100) is thinner than that of the areas where the frame 150 is mounted (the protruding portions 100b and 100c of the metal plate 100).

Also, as shown in FIGS. 6A and 6B, the flexible printed circuit 130 has two types of wiring terminal parts with different terminal pitches, that is, inner portions 130a and outer portions 130b. For example, in each inner portion 130a, a plurality of pads of 0.1 mm×0.3 mm-in-size are aligned in the width direction, while in each outer portion 130b, a plurality of pads of 0.35 mm in width are aligned with a pitch of 0.65 mm in order to prevent a problem such as electrical short-circuit which may occur when the semiconductor laser unit is implemented in the optical disk drive.

The frame 150 has an aperture in the area of its top portion which faces the recessed portion 100a of the metal plate 100. The optical element 160 is attached to the upper surface of the frame 150 with an adhesive such as ultraviolet cure resin so as to cover the aperture. It is preferable to use an adhesive of high viscosity and thixotropy in order to prevent it from spreading over the metal frame 150 or being squeezed out of the aperture of the frame 150.

The frame 150 is fixed on the metal plate 100 by adhesion or laser welding.

In the semiconductor laser unit of the first embodiment as described above, the light emitted from the semiconductor laser 110 rises vertically by a reflecting mirror (not shown in the diagram), passes through the optical element 160 and goes outside the semiconductor laser unit. The light reflected from the optical disk (not shown in the diagram) returns the same path, passes through the optical element 160, and then enters the light-receiving element mounted on the silicon substrate 120.

As described above, in the semiconductor laser unit of the first embodiment, the flexible printed circuit 130, of which end portions extend off the metal plate 100 and are bent along the sides of the metal plate 100, is fixed on the sides of the metal plate 100 by the frame 150. Therefore, the semiconductor laser unit of the first embodiment achieves reduction in its size.

The recessed portion 100a of the metal plate 100 is covered with the frame 150, and the aperture on the top portion of the frame 150 is covered with the optical element 160. Therefore, it becomes possible to prevent dust or the like from entering the light-emitting/receiving unit mounted on the recessed portion 100a. As a result, it becomes possible to install the semiconductor laser unit of the first embodiment in the optical pickup device without loss of the properties of the light-emitting/receiving unit.

The semiconductor laser unit of the first embodiment is assembled by mounting the silicon substrate 120 and the flexible printed circuit 130 on the recessed portion 100a of the metal plate 100. In this manner, no complicated technique is needed for manufacturing the semiconductor laser unit of the first embodiment.

The semiconductor laser unit of the first embodiment uses the flexible printed circuit 130 which allows fine-pitch wiring, as a wiring substrate. Therefore, it becomes possible to reduce the wiring pitch in the inner portion to about one fifth the conventional pitches. As a result, the semiconductor laser unit of the first embodiment achieves both further reduction in size and high-density integration of an increased number of pins for higher performance.

In the semiconductor laser unit of the first embodiment, the thickness of the areas in the metal plate 100 where the frame 150 is mounted (the protruding portions 100b and 100c) is greater than that of the area where the flexible printed circuit 130 and the silicon substrate 120 are mounted (the recessed portion 100a). Therefore, it is possible to keep the frame 150 and the optical element 160 from coming into contact with the wires 140. All that is required is that the recessed portion 100a is deep enough to keep the top portion of the frame 150 and the optical element 160 from coming into contact with the wires 140.

By using the semiconductor laser unit of the first embodiment having the above-described advantages in an optical pickup device of an optical disk drive, a slim and multifunctional optical disk drive is realized.

Furthermore, in the semiconductor laser unit of the first embodiment, the silicon substrate 120 is mounted on (the recessed portion 100a of) the metal plate 100. Therefore, all the elements directly below the light-emitting/receiving unit that is a heat generating source are made of metal, and thus the semiconductor laser unit of the first embodiment is capable of dissipating the heat easily. As a result, by using the semiconductor laser unit of the first embodiment in an optical pickup device of an optical disk drive, it becomes possible to realize an optical disk drive which can be used at a higher temperature.

It should be noted that, in the above description of the assembly processes using FIG. 5, the flexible printed circuit 130 is mounted on the metal plate 100 before the silicon substrate 120 is mounted thereon, but the silicon substrate 120 may be mounted on the metal plate 100 before the flexible printed circuit 130 is mounted thereon.

As shown in FIG. 5C and FIG. 6B, the optical element 160 made of transparent glass is mounted on the outer surface of the frame 150 in the first embodiment. However, as shown in FIG. 7, the optical element 160 may be mounted on the inner surface of the frame 150. Since the aperture of the top portion of the frame 150 is also covered with the optical element 160 in this case, it is possible to prevent dust and the like from entering the light-emitting/receiving unit. Therefore, it becomes possible to install the semiconductor laser unit shown in FIG. 7 in the optical pickup device without loss of the properties of the light-emitting/receiving unit.

Also, in the above description, the optical element 160 is firmly fixed to the frame 150 with an adhesive after the frame 150 is fixed to the metal plate 100. However, the frame 150, to which the optical element 160 is previously fixed using a low-melting glass, may be fixed to the metal plate 100.

The metal plate 100 is not limited to the plate made of copper. It is possible to reduce the cost if copper is used.

Transparent resin may be filled in the space created between the metal plate 100 and the frame 150.

The frame 150 also has an effect of preventing unnecessary light from entering the light-receiving element placed in the recessed portion 100a. The frame 150 does not need to be made of metal.

Furthermore, in the first embodiment, the recessed portion 100a is formed between the protruding portions 100b and 100c in the metal plate 100, as shown in FIG. 5A. However, the recessed portion 100a may be surrounded by one protruding portion.

### Second Embodiment

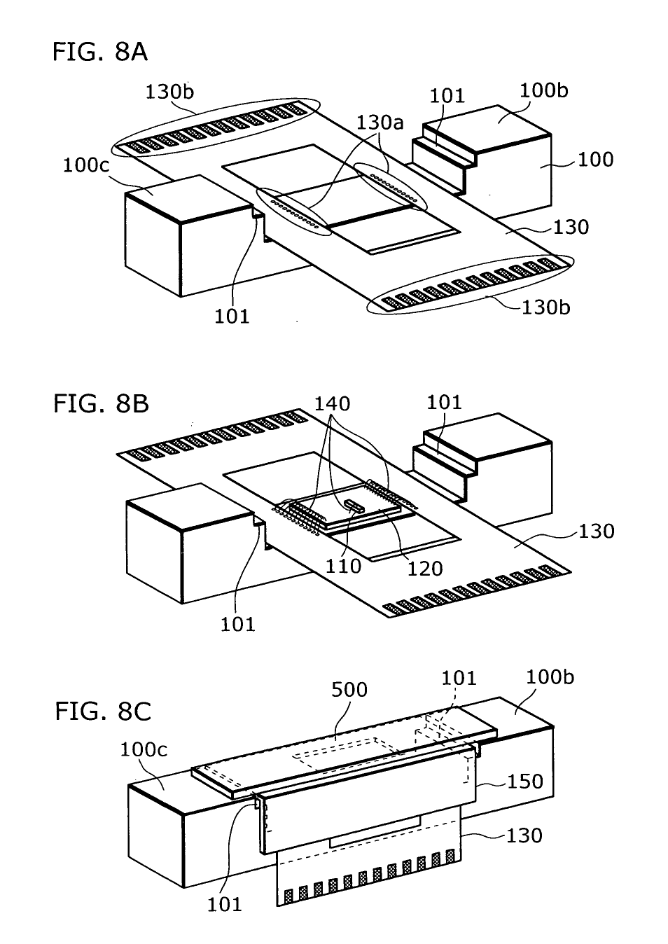

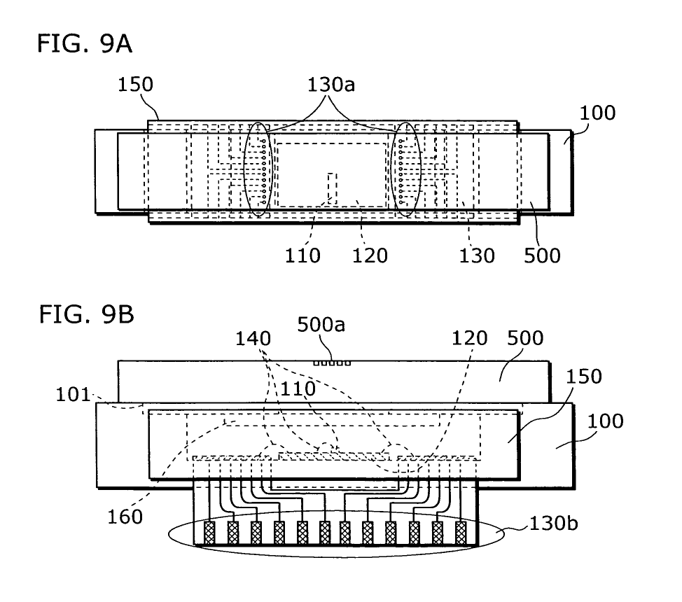

Next, a semiconductor laser unit of a second embodiment is described below with reference to FIGS. 8A to 8C and FIGS. 9A and 9B.

FIGS. 8A to 8C are exploded perspective views of a semiconductor laser unit of the second embodiment. FIG. 9A is a top view of such semiconductor laser unit, and FIG. 9B is a side view of the semiconductor laser unit. It should be noted that the same reference numbers are assigned to the elements common to those in FIGS. 5A to 6B, and the detailed description thereof is not repeated here.

As with the semiconductor laser unit of the first embodiment, in the semiconductor laser unit of the second embodiment, the thickness of the areas in the metal plate 100 where the frame 150 is mounted (the protruding portions 100b and 100c) is also greater than that of the area where the silicon substrate 120 and the flexible printed circuit 130 are mounted (the recessed portion 100a).

However, the semiconductor laser unit of the second embodiment differs from that of the first embodiment in that second recessed portions 101 are formed on the opposing side surfaces of the protruding portions 100b and 100c of the metal plate 100 where the frame 150 is placed. The depth of each second recessed portion 101 (difference in level between the top of each of the protruding portions 100b and 100c and the bottom of each second recessed portion 101) is greater than the thickness of the top portion of the frame 150, and the frame 150 is placed on these second recessed portions 101. Therefore, as shown in FIG. 8C and FIG. 9B, it becomes possible to firmly fix a plate-type optical element 500 on the thickest parts (the thickest parts of the protruding portions 100b and 100c) of the metal plate 100.

The semiconductor laser unit of the second embodiment as mentioned above includes: the metal plate 100; the semiconductor laser 110; the silicon substrate 120; the flexible printed circuit 130; the wires 140; the frame 150 which is made of metal and used for fixing the bent parts of the flexible printed circuit 130 on the sides of the metal plate 100; the optical element 160 of a light-transparent glass plate which is placed on the inner surface of the frame 150; and a plate-type optical element 500 which is placed on the upper surfaces of the protruding portions 100b and 100c of the metal plate 100 and allows the incident light to pass through and diffract.

A hologram pattern 500a for diffracting the light reflected from the optical disk so as to guide it into the light-receiving unit is provided on the underside of the top of the optical element 500 (that is the surface farther from the semiconductor laser 110 than the bottom surface of the optical element 500). The optical element 500 is attached and fixed on the metal plate 100 with an adhesive such as ultraviolet cure resin after it is placed on the protruding portions 100b and 100c of the metal plate 100 and the optical axis thereof is adjusted to the light-emitting point.

The optical element 500 is placed on the metal plate 100, not on the frame 150, because the distance between the light-emitting/receiving unit and the hologram pattern 500a is important for effective use of light beam and it becomes possible to raise the accuracy of the distance if the optical element 500 is placed on the metal plate 100. If the optical element 500 is placed on the frame 150 of the semiconductor laser unit of the first embodiment, the thickness of the top portion of the frame 150 and the variations in the thicknesses affect the distance between the light-emitting/receiving unit and the hologram pattern 500a, and therefore it becomes impossible to obtain desired light-receiving properties stably.

As described above, the semiconductor laser unit of the second embodiment includes the optical element 500 having the hologram pattern 500a for diffracting the light reflected from the optical disk. In other words, in the semiconductor laser unit of the second embodiment, the optical element is integrated into the main body of the semiconductor laser unit, although the conventional optical element is placed outside the unit. Therefore, by using the semiconductor laser unit of the second embodiment, the process for manufacturing the optical disk drive is simplified more than ever before.

The optical element 500 is placed on the protruding portions 100b and 100c of the metal plate 100, not on the frame 150. As a result, the accuracy of the distance between the light-emitting/receiving unit and the hologram pattern is ensured, which means that the light diffracted by the hologram pattern reliably enters the light-receiving element.

Furthermore, in the second embodiment, the recessed portion 100a of the metal plate 100 is formed between the protruding portions 100b and 100c in the metal plate 100, as shown in FIG. 8A. However, the recessed portion 100a may be surrounded by one protruding portion. In such a case, the second recessed portion 101 is formed on the inner wall of the protruding portion, and the top portion of the frame 150 is placed on such second recessed portion 101.

### Third Embodiment

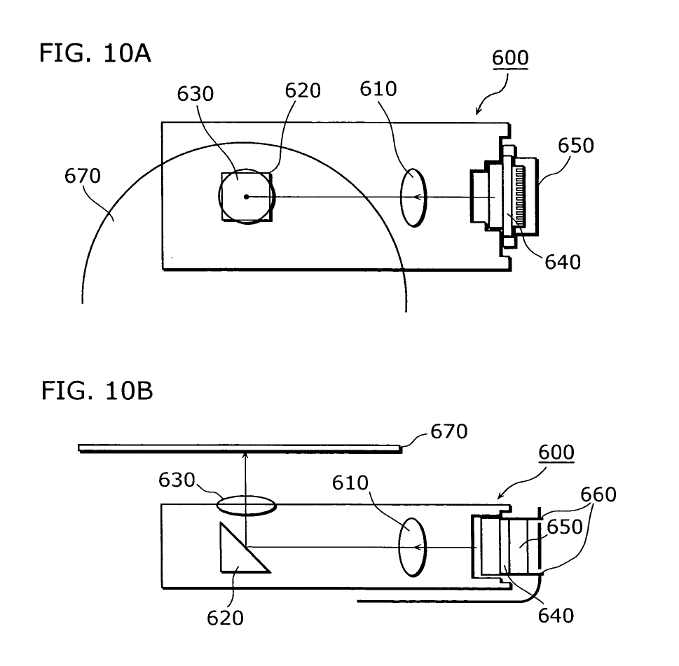

An optical pickup device of the third embodiment is described below with reference to FIGS. 10A and 10B.

FIG. 10A is a top view of an optical pickup device 600 of the third embodiment, and FIG. 10B is a section view of the optical pickup device 600 of the third embodiment.

The optical pickup device 600 is a device for reading data from an optical disk 670, and includes: a collimating lens 610; a reflecting mirror 620; an objective lens 630; a semiconductor laser unit 640 of the first or second embodiment; and a heat dissipation block 650 which is attached and fixed on the underside of the metal plate of the semiconductor laser unit 640 with an adhesive such as a silicon-type thermal conductive adhesive.

The flexible printed circuit of the optical pickup and the flexible printed circuit of the semiconductor laser unit 640 are connected to each other by wires at the outer portions of the flexible printed circuit of the semiconductor laser unit 640, that is, at soldered connection points 660 outside of the optical pickup device 600, as shown in FIG. 10B.

As described above, the optical pickup device 600 includes the heat dissipation block 650 on the underside of the metal plate of the semiconductor laser unit 640, and the metal plate and the optical pickup device 600 are in contact with each other. Therefore, the heat dissipation area significantly increases and the head dissipation effect increases, and thus it becomes possible to efficiently dissipate the heat generated in the semiconductor laser outside of the device. As a result, the optical pickup device 600 of the present embodiment operates stably.

In the semiconductor laser unit 640 in the optical pickup device 600 of the present embodiment, the flexible printed circuit is used as a wiring substrate. The flexible printed circuit of the semiconductor laser unit 640 and the flexible printed circuit of the optical pickup device 600 are connected by wires at the soldered connection points 660 outside of the optical pickup device 600. As a result, it becomes possible to ensure twice the distance between the optical element and the outer portion of the flexible printed circuit that is the soldered connection point at which they are connected to each other than the conventional structure, and therefore the optical pickup device 600 of the present embodiment significantly reduces the thermal load on the semiconductor laser unit 640.

More specifically, the optical element and the outer portion of the flexible printed circuit are placed apart from each other, and therefore the adhesive for fixing the optical element by thermal conduction is not heated beyond the allowable heat-resistant temperature when the wires are connected by soldering. As a result, an antireflection film does not fall off the grating pattern or the hologram pattern of the optical element, nor is the optical element displaced due to softening of the adhesive, and therefore neither the properties nor the reliability of the optical element deteriorates.

It should be noted that in the optical pickup device 600 of the present embodiment, the metal plate of the semiconductor laser unit 640 and the heat dissipation block 650 are firmly bonded by a silicon-type adhesive, but the present invention is not limited to such silicon-type adhesive. Any highly thermal conductive adhesive, for example, a highly thermal conductive graphite sheet, may be used.

### INDUSTRIAL APPLICABILITY

The semiconductor laser unit of the present invention can be used for an optical pickup device of an optical disk drive and the like.

What is claimed is:

1. A semiconductor laser unit comprising:
a metal plate having a first recessed portion in a central part of an upper surface of said metal plate;
a flexible printed circuit which has wiring patterns, and a first aperture positioned on the first recessed portion, and is bent at both ends and in contact with the first recessed portion and a pair of side surfaces of said metal plate;
a light-emitting/receiving unit which includes a light-emitting element and a light-receiving element, and is placed on the first recessed portion through the first aperture;
a frame having side portions and a top portion, the side portions fixing firmly, on the side surfaces of said metal plate, said flexible printed circuit which is in contact with the side surfaces, the top portion having a second aperture and being placed on a protruding portion of said metal plate so that the first recessed portion is covered with the top portion and the second aperture faces toward the first recessed portion; and
an optical element which covers the second aperture.

2. The semiconductor laser unit according to claim 1,
wherein the protruding portion of said metal plate, surrounding the first recessed portion, has a second recessed portion having a depth greater than the thickness of the top portion of said frame, and
the top portion of said frame is placed on the second recessed portion.

3. The semiconductor laser unit according to claim 1,
wherein said optical element has a pattern for diffracting incident light.

4. The semiconductor laser unit according to claim 1,
wherein said metal plate is made of metal including copper.

5. An optical pickup device comprising a semiconductor laser unit,
wherein said semiconductor laser unit includes:
a metal plate having a first recessed portion in a central part of an upper surface of said metal plate;
a flexible printed circuit which has wiring patterns, and a first aperture positioned on the first recessed portion, and is bent at both ends and in contact with the first recessed portion and a pair of side surfaces of said metal plate;
a light-emitting/receiving unit which includes a light-emitting element and a light-receiving element, and is placed on the first recessed portion through the first aperture;
a frame having side portions and a top portion, the side portions fixing firmly, on the side surfaces of said metal plate, said flexible printed circuit which is in contact with the side surfaces, the top portion having a second aperture and being placed on a protruding portion of said metal plate so that the first recessed portion is covered with the top portion and the second aperture faces toward the first recessed portion; and
an optical element which covers the second aperture.
